(19) United States
(12) Patent Application Publication
(10) Pub. No.: US 2018/0376618 A1
(43) Pub. Date: Dec. 27, 2018

(54) THERMALLY CONDUCTIVE MEMBER

(71) Applicant: JOINSET CO., LTD., Ansan-si (KR)

(72) Inventors: Kee-Han Park, Ansan-si (KR); Seong-Jin Lee, Ansan-si (KR); Sun-Ki Kim, Gunpo-si (KR)

(73) Assignee: JOINSET CO., LTD.

(21) Appl. No.: 16/019,835

(22) Filed: Jun. 27, 2018

(30) Foreign Application Priority Data
Jun. 27, 2017 (KR) 10-2017-0081499
Aug. 9, 2017 (KR) 10-2017-0100875
Aug. 9, 2017 (KR) 10-2017-0101358
Nov. 7, 2017 (KR) 10-2017-0147125

(51) Int. Cl. H05K 7/20; H01L 23/373

(52) U.S. Cl. CPC H05K 7/20481; B32B 7/12; H01L 23/3735

(57) ABSTRACT

Disclosed is a thermally conductive member which is interposed between electrically conductive objects facing each other and transfers heat. The thermally conductive member includes a metal base sheet having a certain thickness and a thermally conductive rubber sheet which adheres and is stacked to one surface of the base sheet through curing or a physical force and has elasticity. While the thermally conductive rubber sheet is stacked on the base sheet, edge portions of the base sheet are removed by light exposure and chemical etching and edges of the base sheet are located further inside than edges of the rubber sheet such that a margin portion is formed on corresponding portion of the base sheet. The rubber sheet is cut with a cutter mold at the margin portion.

### REFERENCE TO RELATED APPLICATIONS

This application claims the priority benefit of Korean Patent Application No. 10-2017-0081499 filed on Jun. 27, 2017 and Korean Patent Application No. 10-2017-0100875 filed on Aug. 9, 2017, and Korean Patent Application No. 10-2017-0101358 filed on Aug. 9, 2017, and Korean Patent Application No. 10-2017-0147125 filed on Nov. 7, 2017, the entire contents of which are incorporated herein by reference.

### FIELD OF THE INVENTION

The present invention relates to a thermally conductive member, and more particularly, to a thermally conductive member which is easily manufactured and allows objects to maintain reliable electrical insulation.

### BACKGROUND OF THE INVENTION

As electronic devices and information and communications apparatuses have been miniaturized and integrated, heat, static electricity, electromagnetic waves have a strong influence. For example, as electronic components, a microprocessor has an increasingly higher processing speed and a memory semiconductor has a degree of integration which increases as a capacity increases such that a lot of heat and electromagnetic waves are generated and there is a large amount of influence of heat, static electricity, and electromagnetic waves.

Generally, a thermally conductive silicone rubber sheet is applied to a space between an electronic component which generates heat and a case which accommodates the electronic component which generates heat such that the case is used as a cooling unit through which heat is released.

Korean Patent Registration No. 1022036, filed by the applicant and registered, discloses an elastic thermally conductive pad which includes a thermally conductive non-foaming elastic body having a certain volume, a metal foil which adheres to at least one surface of the thermally conductive non-foaming elastic body, and a thermally conductive non-foaming elastic adhesive interposed between the thermally conductive non-foaming elastic body and the metal foil to join the thermally conductive non-foaming elastic body and the metal foil through curing.

According to the general thermally conductive member, the thermally conductive non-foaming elastic body and the metal foil have the same areas such that the metal foil stretches when being cut with a cutter and burrs are formed during a manufacturing process. Accordingly, it is impossible to maintain reliable electrical insulation between electrically conductive objects which are disposed on both sides of the thermally conductive member and face each other due to sparks which occur there between.

Also, since when the thermally conductive non-foaming elastic adhesive is applied, a thickness thereof increases necessarily, the above structure is inappropriate for a thermally conductive member having a small thickness, for example, a thickness of 1 mm or less.

### SUMMARY OF THE INVENTION

The present invention is directed to providing a thermally conductive member which is interposed between objects facing each other and is capable of maintaining reliable electrical insulation between the objects.

The present invention is also directed to providing a thermally conductive member which has elasticity and has a structure adequate for a small thickness.

The present invention is also directed to providing a thermally conductive member having a structure which is easily manufactured.

The present invention is directed to providing a thermally conductive member capable of being reliably separated when the thermally conductive member is picked up and released from a vacuum at a corresponding position by a vacuum pick-up unit and is separated from a nozzle.

According to an aspect of the present invention, there is provided a thermally conductive member interposed between objects facing each other to transfer heat. The thermally conductive member includes a metal base sheet having a certain thickness and a thermally conductive rubber sheet which adheres and is stacked to one surface of the base sheet through curing and has flexibility. Here, while the thermally conductive rubber sheet is stacked, edge portions of the base sheet are removed and edges of the base sheet are located further inside than edges of the rubber sheet such that a margin portion for electrical insulation between the objects is formed on corresponding portions of the base sheet. Also, the rubber sheet is cut with a cutter mold at the margin portion.

According to another aspect of the present invention, there is provided a thermally conductive member interposed between electrically conductive objects facing each other to transfer heat. The thermally conductive member includes a metal base sheet having a certain thickness and a thermally conductive rubber sheet which adheres and is stacked to one surface of the base sheet through curing and has elasticity. Here, edges of the base sheet are located further inside than edges of the rubber sheet such that a margin portion for electrical insulation between the objects is formed on corresponding portions of the base sheet. Also, while a plurality of such base sheets are arranged at certain intervals, spaces corresponding to the intervals are filled with a mask materials and a liquid thermally conductive paste corresponding to the rubber sheet is applied to the entire surface and cured and then the rubber sheet is cut out of the mask material by using a cutter mold.

According to another aspect of the present invention, there is provided a thermally conductive member interposed between objects facing each other to transfer heat. The thermally conductive member includes a metal base sheet having a certain thickness, a thermally conductive rubber sheet which adheres and is stacked to one surface of the base sheet through curing and has flexibility, and a thermally conductive sheet which adheres to another surface of the base sheet, has an area smaller than an area of the base sheet, and has elasticity. Here, edges of the base sheet are located further inside than edges of the rubber sheet such that a margin portion for electrical insulation between the objects is formed at corresponding portions of the base sheet. Also, the rubber sheet is cut with a cutter mold at the margin portion.

According to another aspect of the present invention, there is provided a thermally conductive member interposed between objects facing each other. The thermally conductive member includes a stacked body which includes a metal base sheet having a certain thickness and a rubber layer formed by adhering to one surface of the base sheet through curing and a thermally conductive rubber sheet which adheres to the rubber layer due to magnetic adhesion of the rubber layer and has elasticity. Here, the stacked body is formed by cutting with a cutter such that the base sheet and the rubber layer have the same size. Also, edges of the stacked body are located further inside than edges of the rubber sheet such that a margin portion for electrical insulation between the objects is formed between the edges of the stacked body and the rubber sheet.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1A is a perspective view of a thermally conductive member according to one embodiment of the present invention;

FIG. 1B is a side view of the thermally conductive member according to one embodiment of the present invention;

FIG. 1C is a side view illustrating a deformed structure of the thermally conductive member;

FIG. 2 illustrates an example of applying the thermally conductive member of FIG. 1A;

FIG. 3 is a side view of a thermally conductive member according to another embodiment of the present invention;

FIG. 4 is a side view of a thermally conductive member according to another embodiment of the present invention;

FIG. 5A is a perspective view of a thermally conductive member according to another embodiment of the present invention;

FIG. 5B is a side view of the thermally conductive member according to another embodiment of the present invention;

FIG. 6 illustrates an example of applying the thermally conductive member of FIG. 5A;

FIG. 7 is a side view of a thermally conductive member according to another embodiment of the present invention; and

FIG. 8 is a side view of a thermally conductive member according to another embodiment of the present invention.

### DETAILED DESCRIPTION OF THE INVENTION

Hereinafter, embodiments of the present invention will be described in detail with reference to the attached drawings. It is noted that the embodiments are provided to one of ordinary skill in the art only to completely understanding of the present invention.

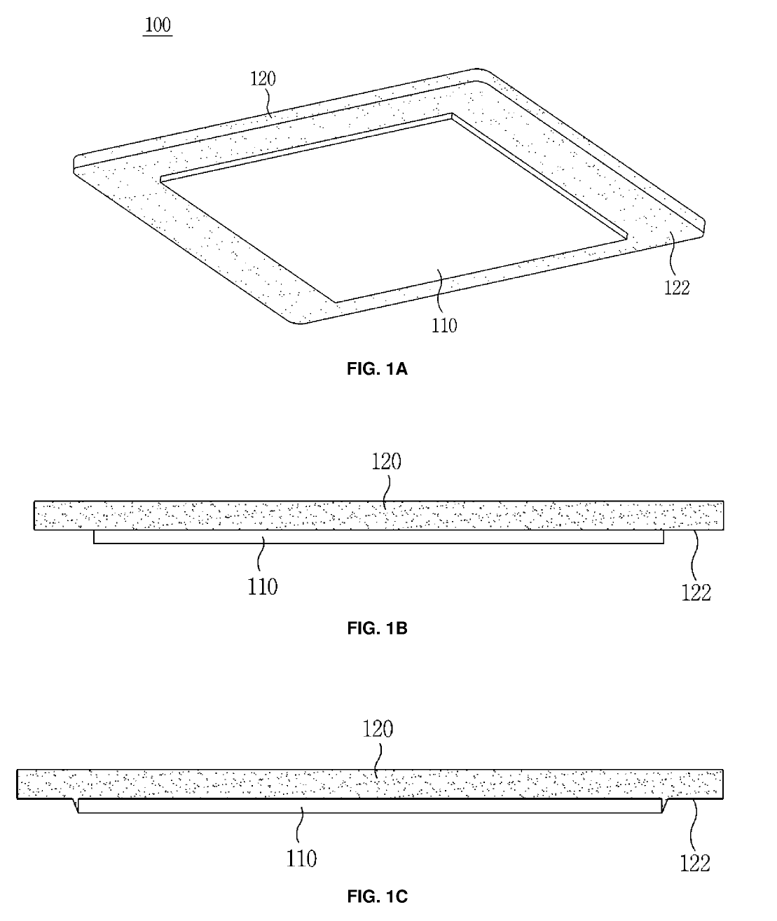

FIG. 1A is a perspective view of a thermally conductive member according to one embodiment of the present invention, FIG. 1B is a side view of the thermally conductive member according to one embodiment of the present invention, and FIG. 1C is a side view illustrating a deformed structure of the thermally conductive member.

The thermally conductive member 100 is disposed between objects facing each other and transfers heat generated by one side to the other side.

The objects may be a heating element and a cooling unit formed of a metallic material, and heat emitted by the heating element is transferred to the cooling unit so as to cool the heat of the heating element.

For example, the thermally conductive member 100 may be disposed between an electronic component mounted on a printed circuit board (PCB) and a case formed of a metal and may transfer heat generated by the electronic component to the case. The electronic component may be a semiconductor chip, an integrated chip (IC), a light emitting diode (LED), or the like, and the case may be a heat sink, a cover, or a bracket.

When the objects include electrical conductivity in addition to thermal conductivity, it is necessary to maintain adequate electrical insulation therebetween and the thermally conductive member 100 needs to electrically separate the objects from each other.

The thermally conductive member 100 includes a metal base sheet 110 and a thermally conductive rubber sheet 120 stacked on a top surface of the metal base sheet 110.

The base sheet 110 may be formed of a metallic material including copper or a copper alloy having a certain thickness and high thermal conductivity and may include electrical conductivity to be used as an electromagnetic wave shield.

For example, when stainless steel which is cheap is used, since thermal conductivity thereof is lower than that of copper but strength thereof is higher than that of copper, it is possible to provide a base sheet having a thinner thickness.

The base sheet 110 may be a heat pipe or a vapor chamber formed of a metallic material in a single body or a plane with a space therein. Particularly, in the case of the heat pipe or the vapor chamber, heat may be quickly transferred by an operation of a liquid heat transfer medium accommodated in the space.

A thickness of the rubber sheet 120 is formed to be thicker than a thickness of the base sheet 110 such that there are provided advantages in which the thermally conductive member 100 may be further pushed by the same force and may have high elasticity. For example, the thickness of the base sheet 110 may be 0.01 mm to 0.15 mm, and the thickness of the rubber sheet 120 may be 0.03 mm to 0.8 mm.

An electrically conductive adhesive tape or an electrically conductive gasket may be attached to a bottom surface of the base sheet 110 and will be described below.

When the base sheet 110 is copper or a copper alloy, an exposed surface of the base sheet 110 may be coated with nickel, tin, silver, or gold to be prevented from being corroded.

The thermally conductive rubber sheet 120 may be thermosetting, may include elasticity and flexibility, and may adhere to the top surface of the base sheet 110 through curing. In other words, when a liquid thermally conductive paste is applied to the top surface of the base sheet 110, the liquid thermally conductive paste is cured so as to form the thermally conductive rubber sheet 120 and adhere to the base sheet 110.

Also, a bottom surface of the thermally conductive rubber sheet 120 is separately manufactured to have magnetic adhesion so as to magnetically adhere to the top surface of the base sheet 110.

According to the above structure, since an additional adhesive is not applied, it is adequate to embody a thermally conductive member having a thickness of 1 mm or less.

As described above, when the objects include electrical conductivity as well as thermal conductivity, it is necessary to maintain adequate electrical insulation. For this, the rubber sheet 120 may be an electrical insulation.

According to the embodiment, a size of the base sheet 110 is smaller than a size of the rubber sheet such that edges of the base sheet 110 are located further inside than edges of the rubber sheet 120.

As a result thereof, a margin portion 122 having a certain width is formed on the base sheet 110 between the edges of the base sheet 110 and the edges of the rubber sheet 120. In the embodiment, the width of the margin portion 122 may be uniformly formed along the edges of the base sheet 110 but is not limited thereto.

Although it is unnecessary to form the margin portion 122 continuously along the edges of the rubber sheet 120, the margin portion 122 may be formed to be capable of substantially maintaining electrical insulation between the electrically conductive objects facing each other.

The margin portion 122 may be formed using a variety of methods. Referring to FIG. 1B, while the rubber sheet 120 adheres to the base sheet 110, a part of the base sheet 110 corresponding to the margin portion 122 may be removed by light exposure and etching such that the margin portion 122 having a uniform width may be formed.

When the base sheet 110 is removed using light exposure and chemical etching, the margin portion 122 may be easily formed on the rubber sheet 120 and the rubber sheet 120 may be cut using a cutter without effects on the base sheet 110 such that there is an effect of easily manufacturing the same.

Removing of the base sheet 110 by light exposure and chemical etching and cutting of the rubber sheet 120 may be easily performed by a roll-to-roll process.

Referring to FIG. 10, while a plurality of such base sheets 110 adhere to, for example, a film at certain intervals, spaces corresponding to the intervals are filled with a mask material and then a liquid thermally conductive paste is applied overall, cured, and then cut such that the thermally conductive member 100 is completed.

In this case, the liquid thermally conductive paste infiltrates into a gap between the masking material and the base sheet 110 and cured such that a shape as shown in FIG. 10 may be obtained.

In this example, since the margin portion 122 may be formed on the rubber sheet 120 without processing through a light exposure and etching process, manufacturing costs are low. Also, since it is unnecessary to use an etching solution, there is no change in properties of the rubber sheet 120 caused by the etching solution.

As described above, since reliable electrical insulation between the electrically conductive objects facing each other may be maintained by forming the margin portion 122. Also, when the rubber sheet 120 is cut using a cutter mold, since the base sheet 110 is not present at a cut part, only the rubber sheet 120 is cut.

As a result thereof, in general, a base sheet, which elongates well, stretches to protrude like a type of burr when being cut such that electrical insulation between objects facing each other becomes a problem. However, since it is necessary to cut only the rubber sheet 120, reliable electrical insulation may be maintained.

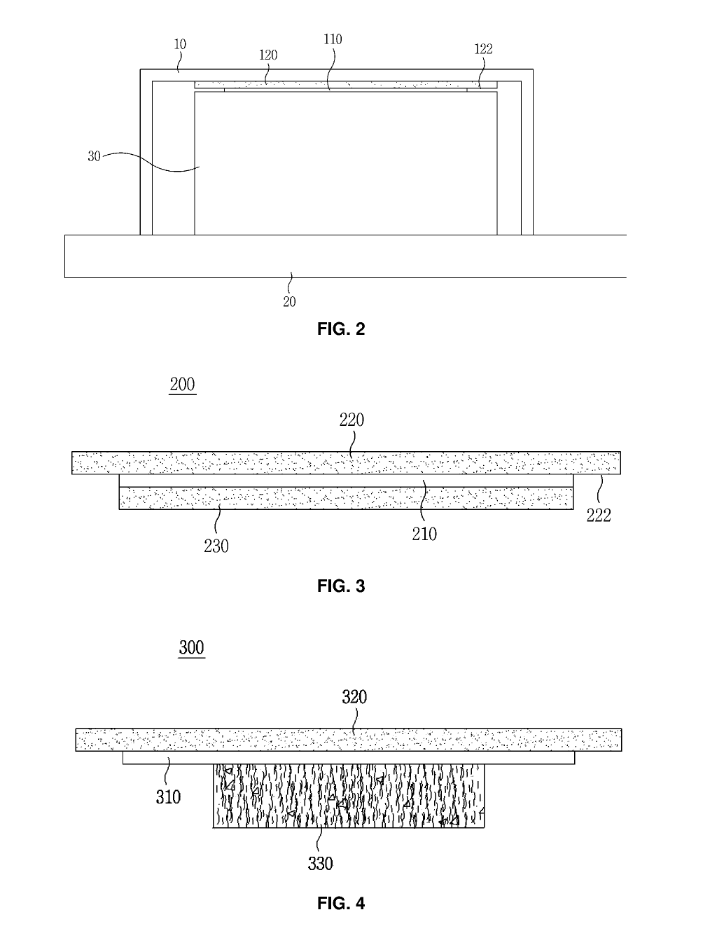

FIG. 2 illustrates an example of applying the thermally conductive member of FIG. 1A.

The thermally conductive member 100 is disposed between objects 10 and 20 facing each other to transfer heat generated by one of the objects 10 and 20 to the other of the objects 10 and 20 and simultaneously with maintaining reliable electrical insulation between the objects 10 and 20. For example, heat generated by an electronic component 30 mounted on a PCB 20 is transmitted to a metal case 10 through the thermally conductive member 100 and released.

The base sheet 110 of the thermally conductive member 100 may come into direct contact with the electronic component 30 or may come into contact therewith interposing an electrically conductive adhesive tape or gasket therebetween as described above. The thermally conductive rubber sheet 120 comes into contact with an inner surface of the metal case 10.

Here, since the margin portion 122 of the rubber sheet 120 and the electronic component 30 are spaced a certain gap apart, it is possible to prevent contact or sparks between the metal case 10 and the electronic component 30 such that reliable electrical insulation may be maintained.

Also, since the base sheet 110 is formed of a metal material, electromagnetic waves may be blocked. Due to properties of a material of the rubber sheet 120, the thermally conductive member 100 may have elasticity.

In FIG. 2, the base sheet 110 may come into contact with the case 10 and the rubber sheet 120 may come into contact with the electronic component 30 or the base sheet 110 may come into contact with the electronic component 30 interposing another elastic thermally conductive member therebetween.

FIG. 3 is a side view of a thermally conductive member according to another embodiment of the present invention.

According to the embodiment, a thermally conductive member 200 includes a metal base sheet 210 and thermally conductive rubber sheets 220 and 230 stacked on a top surface and a bottom surface of the metal base sheet 210, respectively.

The thermally conductive rubber sheet 220 is formed to be larger than the base sheet 210 such that edges of the base sheet 210 may be located further inside than edges of the corresponding thermally conductive rubber sheet 220 and a margin portion 222 may be formed. The thermally conductive rubber sheet 230 may have the same size as that of the base sheet 210.

According to the embodiment, the base sheet 210 does not come into direct contact with objects and each of the thermally conductive rubber sheets 220 and 230 comes into contact with objects.

Accordingly, since a reliability of contact with objects may be increased, thermal conductivity may increase.

FIG. 4 is a side view of a thermally conductive member according to another embodiment of the present invention.

According to the embodiment, a thermally conductive sheet 330, which has an area smaller than an area of a base sheet 310 and has elasticity, adheres to a bottom surface of the base sheet 310.

The thermally conductive sheet 330 may be electrically (semi) conductive and includes any one of carbon powder, carbon fibers, carbon tubes, and graphite therein.

As described above, a thermally conductive member 300 includes the base sheet 310, a rubber sheet 320 which adheres to a top surface of the base sheet 310, and the thermally conductive sheet 330 which adheres to the bottom surface of the base sheet 310 and includes at least carbon components to have electrical (semi) conductivity such that the thermally conductive sheet 330 may come into mechanically elastic contact with a heating element.

A thickness of the thermally conductive sheet 330 may be thicker than those of the base sheet 310 and the rubber sheet 320.

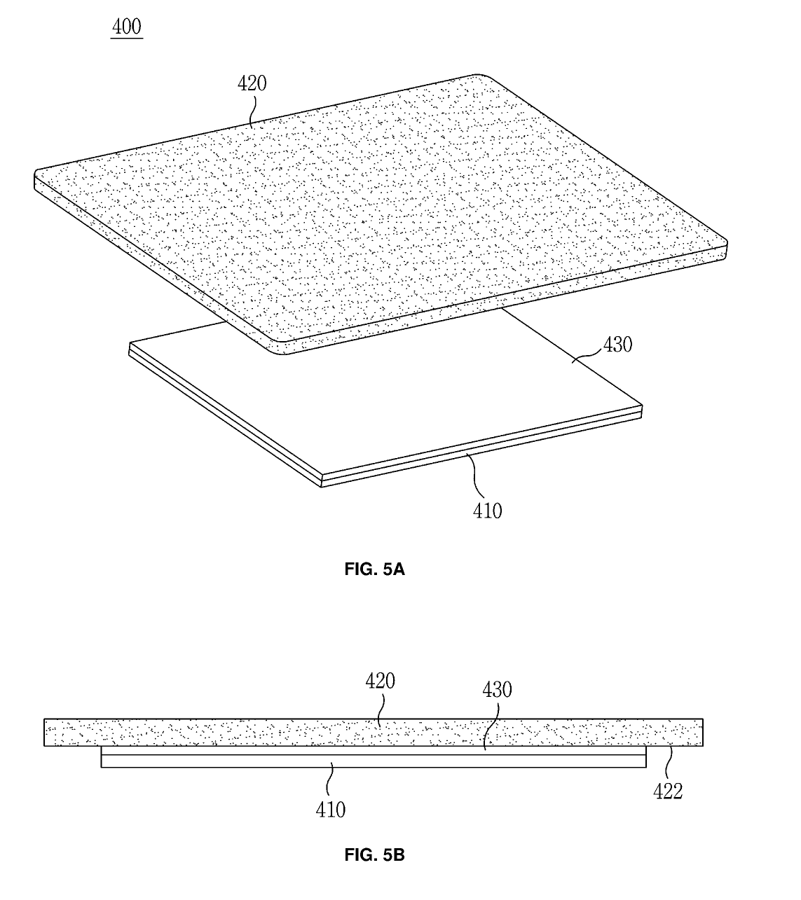

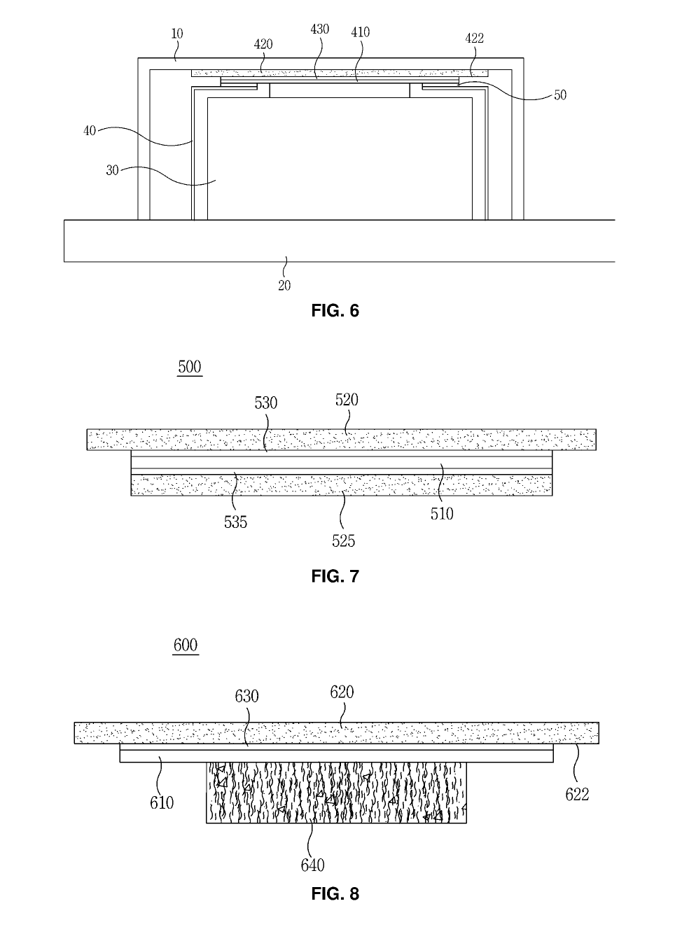

FIG. 5A is a perspective view of a thermally conductive member according to another embodiment of the present invention, FIG. 5B is a side view of the thermally conductive member according to another embodiment of the present invention, and FIG. 6 illustrates an example of applying the thermally conductive member of FIG. 5A.

A thermally conductive member 400 includes a base sheet 410 formed of a metal material having electrical conductivity, a rubber layer 430 formed by adhering to a top surface of the base sheet 410, and a thermally conductive rubber sheet 420 which adheres to a top surface of the rubber layer 430.

A silicone-based primer may be disposed between the base sheet 410 and the rubber layer 430, and the rubber layer 430 may be more properly and may reliably adhere to the base sheet 410 by the primer.

The rubber layer 430 may be interpreted as a medium which has low hardness and a thin thickness and is used for improving adhesion of the rubber sheet 420 and the base sheet 410 (hereinafter, referred to as including adhesive forces).

The rubber layer 430 is formed by applying and curing a liquid paste which has flexibility, is thermosetting, and corresponds to the rubber layer 430 to a top surface of the base sheet 410. Here, the rubber layer 430 may have magnetic adhesion through curing and may maintain coupling with the base sheet 410 due to the magnetic adhesion.

Since the rubber layer 430 is formed by applying and curing the liquid paste on the top surface of the base sheet 410 and is cut into a set size by using a cutter, as shown in FIG. 5B, a size of the base sheet 410 is equal to a size of the rubber layer 430.

The rubber layer 430 has thermal conductivity obtained by mixing a rubber with thermally conductive powder so as to provide the thermally conductive member 400 with high thermal conductivity.

To increase the magnetic adhesion of the base sheet 410 and the rubber sheet 420, the rubber layer 430 may be formed to have a very thin thickness to provide high thermal conductivity instead of reducing an amount of thermally conductive particles mixed in the rubber layer 430.

For example, the rubber layer 430 may be a silicone rubber adhesive and may have a thickness of 0.01 mm to 0.05 mm.

The rubber sheet 420 is a thermally conductive rubber sheet obtained by mixing a rubber with thermally conductive powder, and both the rubber layer 430 and the rubber sheet 420 may be formed of a silicone rubber to have high adhesion therebetween.

The rubber sheet 420 may have hardness of Shore A 30 to 65, thermal conductivity of 1 W to 8 W, and a thickness of 0.04 mm to 1 mm.

The rubber sheet 420 is separately manufactured by punching and combined with the rubber layer 430. The rubber sheet 420 and the rubber layer 430 adhere to each other due to, for example, magnetic adhesion of the rubber layer 430. Here, the magnetic adhesion of the rubber layer 430 may be formed by a chemical reaction caused by at least one of pressure, a temperature, and time.

Optionally, a bottom surface of the rubber sheet 420 includes magnetic adhesion such that the rubber sheet 420 and the rubber layer 430 may magnetically adhere to each other due to the magnetic adhesion of the rubber sheet 420 and the rubber layer 430.

Also, as described above, both the rubber sheet 420 and the rubber layer 430 include silicone rubbers so as to provide proper and reliable adhesion.

An exposed surface, here, a top surface of the rubber sheet 420 may not have magnetic adhesion or may have minimum magnetic adhesion to be reel-taped so as to easily perform vacuum pick-up and place.

To allow the thermally conductive member 400 to have high thermal conductivity and to easily transfer heat, the thickness of the rubber sheet 420 is formed to be thicker than those of the thickness of the rubber layer 430 and a thickness of the base sheet 410. The rubber sheet 420 has higher hardness and thermal conductivity than those of the rubber layer 430.

The rubber sheet 420 is formed to be larger than the base sheet 410 such that a margin portion 422 is formed on the rubber sheet 420 between edges of the rubber sheet 420 and edges of the base sheet 410.

Although it is unnecessary to form the margin portion 422 along all the edges of the rubber sheet 420, the margin portion 422 may be formed to be capable of substantially maintaining electrical insulation between electrically conductive objects facing each other.

The rubber layer 430 having low hardness and a thin thickness adheres to the base sheet 410 formed of copper having low mechanical strength such that when they are cut with a cutter, the base sheet 410 stretches and burrs may be formed at a section. When the rubber sheet 420 is thin and the margin portion 422 is not present, the objects facing each other may come into electrical contact with each other due to the burrs.

Accordingly, the electrical contact between the objects caused by the burrs may be prevented by forming the rubber sheet 420 to have an adequate thickness or forming the margin portion 422.

The margin portion 422 may have a width of, for example, 0.05 mm to 2 mm and may be uniformly formed along the edges of the base sheet 410 but is not limited thereto.

The thermally conductive member 400 is manufactured by forming the rubber layer 430 on the base sheet 410 to adhere thereto by casting, cutting a stacked body of the base sheet 410 and the rubber layer into a certain shape by using a cutter or a press mold, preparing an area larger than the stacked body on the rubber layer 430, stacking the rubber sheet 420 which is cut to form the margin portion 422 with respect to the rubber layer 430, and applying a pressure evenly to the rubber sheet 420 to allow the rubber sheet 420 to adhere to the rubber layer 430 due to magnetic adhesion of the rubber layer 430.

Here, when the pressure is applied, heat higher than a certain temperature may be provided to increase adhesion and workability.

The thermally conductive member 400 is wrapped on a reel in a plastic carrier to be easily used for an automation device using an oscillator.

According to the above structure, an exposed surface of the rubber sheet 420 corresponding to an uppermost surface of the thermally conductive member 400 does not have magnetic adhesion or has minimum magnetic adhesion so as not to adhere to a cover film which covers an accommodation portion of a carrier even in contact with the cover film when being wrapped on a reel in the carrier.

Also, the rubber sheet 420 which is an electrical insulation has an area larger than an area of the base sheet 410 to form the margin portion 422 along the edges of the rubber sheet 420 such that reliable electrical insulation is provided by preventing the objects facing each other from being electrically connected to each other by burrs.

Also, since all the base sheet 410, the rubber layer 430, and the rubber sheet 420 are cut with a cutter or partially cut with a press mold such that the margin portion 422 may be formed on the rubber sheet 420 without light exposure and etching processes, manufacturing costs are low. Also, since it is unnecessary to user an etching solution, there is no change in properties of the rubber sheet 420 which is caused by the etching solution.

Also, thicknesses, hardness, and thermal conductivities of the base sheet 410, the rubber layer 430, and the rubber sheet 420 may be adequately designed such that a thermally conductive member having high thermal conductivity may be provided economically.

Referring to FIG. 6, the thermally conductive member 400 is disposed between the objects 10 and 30 facing each other to transfer heat generated by one of the objects 10 and 20 to the other of the objects 10 and 20 and simultaneously with maintaining reliable electrical insulation between the objects 10 and 20. For example, heat generated by the electronic component 30 mounted on the PCB 20 is transmitted to the metal case 10 through the thermally conductive member 400 and released.

The base sheet 410 of the thermally conductive member 400 may come into direct contact with the electronic component 30 or may come into contact therewith interposing an electrically conductive adhesive tape or gasket therebetween as shown in FIG. 6. The thermally conductive rubber sheet 420 comes into contact with an inner surface of the metal case 10.

Here, since the margin portion 422 of the rubber sheet 420 and the electronic component 30 are spaced a certain gap apart, it is possible to prevent contact or sparks between the metal case 10 and the electronic component 30 such that reliable electrical insulation may be maintained.

Meanwhile, the base sheet 410 may adhere to an electromagnetic shield can 40 which covers the electronic component 30 interposing an electrically conductive adhesive tape 50 therebetween so as to shield from electromagnetic waves.

In FIG. 6, the base sheet 410 may come into contact with the case 10 and the rubber sheet 420 may come into contact with the electronic component 30. Otherwise, the base sheet 410 may come into contact with the electronic component 30 interposing another elastic thermally conductive member therebetween.

An exposed surface of the rubber sheet 420 may have no or minimum magnetic adhesion so as to be easily mounted on a desired position in vacuum pickup or vacuum release.

FIG. 7 is a side view of a thermally conductive member according to another embodiment of the present invention.

According to the embodiment, a thermally conductive member 500 includes a base sheet 510 formed of a metal material, rubber layers 530 and 535 formed on both surfaces of the base sheet 510, and thermally conductive rubber sheets 520 and 525 which magnetically adhere to the rubber layers 530 and 535 due to magnetic adhesion of the rubber layers 530 and 535.

The rubber sheet 520 may be formed to be larger than the base sheet 510 such that edges of the base sheet 510 are located further inside than edges of the rubber sheet 520. In this case, the rubber sheet 525 may have the same size as that of the base sheet 510.

According to the embodiment, the base sheet 510 does not come into direct contact with objects and the thermally conductive rubber sheets 520 and 525 come into contact with the objects. Accordingly, since a reliability of contact with the objects may be increased, thermal conductivity may increase.

FIG. 8 is a side view of a thermally conductive member according to another embodiment of the present invention.

According to the embodiment, a thermally conductive sheet 640, which has an area smaller than an area of a base sheet 610 and has elasticity, adheres to a bottom surface of the base sheet 610.

The thermally conductive sheet 640 may be electrically (semi) conductive and includes any one of carbon powder, carbon fibers, carbon tubes, and graphite therein.

In this case, since the thermally conductive sheet 640 is electrically (semi) conductive, a function of a margin portion 622 of the rubber sheet 620 which is an electrical insulation further matters.

As described above, the thermally conductive sheet 640 of the thermally conductive member 600 which includes at least carbon components and has electrical (semi) conductivity may come into mechanically elastic contact with a heating element.

A thickness of the thermally conductive sheet 640 may be thicker than thicknesses of the base sheet 610, the rubber layer 630, and the rubber sheet 620. Thermal conductivity of the thermally conductive sheet 640 is higher than thermal conductivity of the base sheet 610.

According to the embodiments of the present invention, edges of a metal base sheet are located further inside than edges of a rubber sheet and a margin portion is formed on the rubber sheet such that reliable electrical insulation may be maintained between electrically conductive objects facing each other.

Also, when the rubber sheet is cut, since a section corresponds to the margin portion, the base sheet formed of a metal material is removed in this portion such that only the rubber sheet is cut. Accordingly, it is possible to fundamentally prevent a problem in the electrical insulation between the objects facing each other which is caused by the base sheet which well elongates and stretches to protrude like burrs.

Also, the base sheet is removed by light exposure and chemical etching such that the margin portion may be easily formed on the rubber sheet. Accordingly, since it is possible to cut the rubber sheet with no influence on the base sheet, manufacturing thereof may be easily performed.

Also, according to circumstances, high-priced light exposure and etching processes are not used such that manufacturing costs may be reduced economically. Also, an etching solution is not used such that a thermally conductive member including a rubber sheet which is less deformed may be provided.

Also, a rubber layer having a thin thickness and a rubber sheet having high thermal conductivity are stacked such that a thermally conductive member having elasticity and high thermal conductivity may be provided.

Although an exemplary embodiment of the present invention has been described above, it is clear that the present invention may include a variety of changes, modifications, and equivalents thereof and the embodiment may be adequately modified to be equivalently applied. Accordingly, the scope of the present invention defined by the limitation of the following claims is not limited to the above description.

What is claimed is:

1. A thermally conductive member interposed between objects facing each other to transfer heat, comprising:
a metal base sheet having a certain thickness; and
a thermally conductive rubber sheet which adheres and is stacked to one surface of the base sheet through curing and has flexibility,
wherein while the thermally conductive rubber sheet is stacked, edge portions of the base sheet are removed and edges of the base sheet are located further inside than edges of the rubber sheet such that a margin portion for electrical insulation between the objects is formed on corresponding portions of the base sheet, and
wherein the rubber sheet is cut with a cutter mold at the margin portion.

2. The thermally conductive member of claim 1, wherein the base sheet comprises one of copper, a copper alloy, aluminum, and an aluminum alloy.

3. The thermally conductive member of claim 1, wherein the rubber sheet is an electrical insulation.

4. The thermally conductive member of claim 1, wherein the rubber sheet has a thickness thicker than a thickness of the base sheet.

5. The thermally conductive member of claim 1, wherein the rubber sheet is formed by applying a liquid thermally conductive paste corresponding to the rubber sheet to a top surface of the base sheet and curing the thermally conductive paste.

6. The thermally conductive member of claim 1, further comprising another thermally conductive rubber sheet which adheres to another surface of the base sheet through curing.

7. A thermally conductive member interposed between electrically conductive objects facing each other to transfer heat, comprising:
a metal base sheet having a certain thickness; and
a thermally conductive rubber sheet which adheres and is stacked to one surface of the base sheet through curing and has elasticity,
wherein edges of the base sheet are located further inside than edges of the rubber sheet such that a margin portion for electrical insulation between the objects is formed on corresponding portions of the base sheet, and
wherein while a plurality of such base sheets are arranged at certain intervals, spaces corresponding to the intervals are filled with a mask materials and a liquid thermally conductive paste corresponding to the rubber sheet is applied to the entire surface and cured and then the rubber sheet is cut out of the mask material by using a cutter mold.

8. A thermally conductive member interposed between objects facing each other to transfer heat, comprising:
a metal base sheet having a certain thickness;
a thermally conductive rubber sheet which adheres and is stacked to one surface of the base sheet through curing and has flexibility; and
a thermally conductive sheet which adheres to another surface of the base sheet, has an area smaller than an area of the base sheet, and has elasticity,
wherein edges of the base sheet are located further inside than edges of the rubber sheet such that a margin portion for electrical insulation between the objects is formed at corresponding portions of the base sheet, and
wherein the rubber sheet is cut with a cutter mold at the margin portion.

9. The thermally conductive member of claim 8, wherein the thermally conductive sheet is electrically (semi) conductive and comprises any one of carbon powder, carbon fibers, carbon tubes, and graphite.

10. A thermally conductive member interposed between objects facing each other, comprising:
a stacked body which comprises a metal base sheet having a certain thickness and a rubber layer formed by adhering to one surface of the base sheet through curing; and
a thermally conductive rubber sheet which adheres to the rubber layer due to magnetic adhesion of the rubber layer and has elasticity,
wherein the stacked body is formed by cutting with a cutter such that the base sheet and the rubber layer have the same size, and
wherein edges of the stacked body are located further inside than edges of the rubber sheet such that a margin portion for electrical insulation between the objects is formed between the edges of the stacked body and the rubber sheet.

11. The thermally conductive member of claim 10, wherein the rubber sheet has a thicker thickness, higher hardness, and high thermal conductivity than those of the rubber layer.

12. The thermally conductive member of claim 10, wherein the magnetic adhesion of the rubber layer is caused by a chemical reaction according to a pressure, a temperature, and a time.

13. The thermally conductive member of claim 10, wherein the rubber layer is a silicone rubber which is a completely electrical insulation.

14. The thermally conductive member of claim 10, wherein an exposed surface of the rubber sheet has no magnetic adhesion or has magnetic adhesion to a degree of easily performing pickup and release by using a vacuum apparatus.

15. The thermally conductive member of claim 10, wherein the rubber layer is formed by applying a liquid paste corresponding to the rubber layer to one surface of the base sheet and curing the paste.

16. The thermally conductive member of claim 10, further comprising a thermally conductive sheet which adheres to another surface of the base sheet, has an area smaller than an area of the base sheet, and has elasticity.
